(19) United States
(12) Patent Application Publication
(10) Pub. No.: US 2023/0301195 A1
(43) Pub. Date: Sep. 21, 2023

(54) MAGNETIC MEMORY DEVICE

(71) Applicant: Kioxia Corporation, Tokyo (JP)

(72) Inventor: Yuichi ITO, Seoul (KR)

(73) Assignee: Kioxia Corporation, Tokyo (JP)

(21) Appl. No.: 17/943,723

(22) Filed: Sep. 13, 2022

(30) Foreign Application Priority Data
Mar. 18, 2022 (JP) 2022-043734

(51) Int. Cl. H01L 43/08; H01L 27/22; H01L 43/02; G11C 5/08

(52) U.S. Cl. CPC H01L 43/08; G11C 5/08; H01L 27/222; H01L 43/02

(57) ABSTRACT

According to one embodiment, a magnetic memory device includes a magnetoresistance effect element portion, a switching element portion provided on a lower layer side of the magnetoresistance effect element portion, a buffer insulating portion provided between the magnetoresistance effect element portion and the switching element portion, and a conductive portion surrounding a side surface of the buffer insulating portion and electrically connecting the magnetoresistance effect element portion and the switching element portion to each other.

### CROSS-REFERENCE TO RELATED APPLICATIONS

This application is based upon and claims the benefit of priority from Japanese Patent Application No. 2022-043734, filed Mar. 18, 2022, the entire contents of which are incorporated herein by reference.

### FIELD

Embodiments described herein relate generally to a magnetic memory device.

### BACKGROUND

A magnetic memory device has been proposed in which memory cells including magnetoresistance effect elements and selectors (switching elements) are integrated on a semiconductor substrate.

### BRIEF DESCRIPTION OF THE DRAWINGS

FIG. 1 is a perspective view schematically showing a basic configuration of a magnetic memory device according to an embodiment.

FIG. 2 is a cross-sectional view schematically showing a configuration of the magnetic memory device according to the embodiment.

FIG. 3 is a schematic diagram showing a current-voltage characteristic of a selector portion of the magnetic memory device of the embodiment.

FIG. 4 is a diagram schematically showing a magnetoresistance effect element portion, a selector portion, a buffer insulating portion and a conductive portion in relation with each other.

FIGS. 5, 6, 7, 8, 9, 10, 11 and 12 are cross-sectional diagrams schematically illustrating a manufacturing method of the magnetic memory device according to an embodiment.

FIG. 13 is a cross-sectional view schematically showing a modified example of the magnetic memory device of the embodiment.

### DETAILED DESCRIPTION

In general, according to one embodiment, a magnetic memory device includes: a magnetoresistance effect element portion; a switching element portion provided on a lower layer side of the magnetoresistance effect element portion; a buffer insulating portion provided between the magnetoresistance effect element portion and the switching element portion, and a conductive portion surrounding a side surface of the buffer insulating portion and electrically connecting the magnetoresistance effect element portion and the switching element portion to each other.

Embodiments will be described hereinafter with reference to the accompanying drawings.

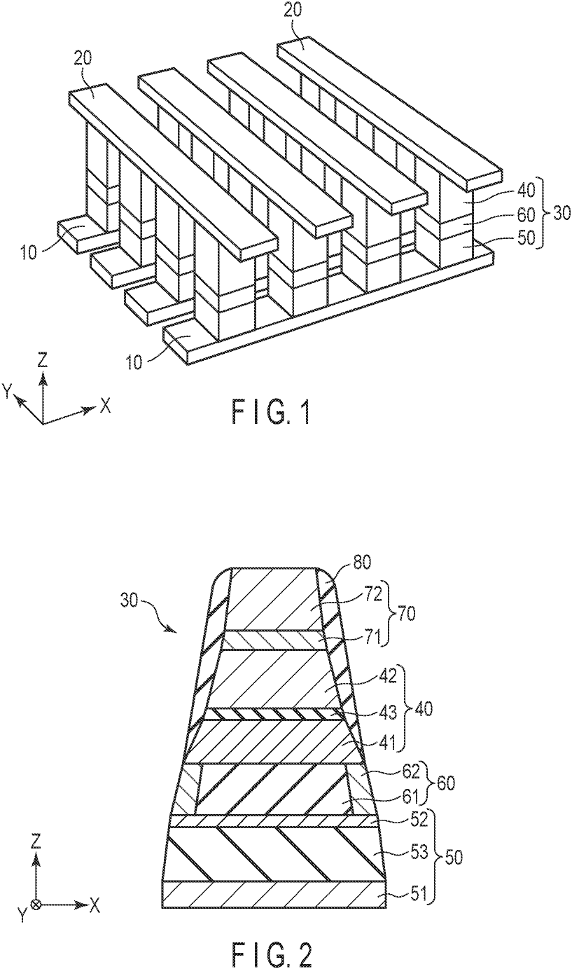

FIG. 1 is a perspective view schematically showing a basic configuration of a magnetic memory device according to an embodiment.

The magnetic memory device of the embodiment includes a plurality of first wiring lines 10 each extending in the X direction, a plurality of second wiring lines 20 each extending in the Y direction and a plurality of memory cells provided between the plurality of first wiring lines 10 and the plurality of second wiring lines 20, respectively.

The first wiring lines 10 corresponds to word lines, respectively and the second wiring lines 20 correspond to bit lines, or the first wiring lines 10 corresponds to bit lines, respectively and the second wiring lines 20 correspond to word lines.

Each memory cell 30 is provided between a respective first wiring line 10 and a respective second wiring line 20, and includes a magnetoresistance effect element portion 40 and a selector portion (switching element portion) 50 provided on a lower layer side of the magnetoresistance effect element portion 40, and an intermediate portion 60 provided between the magnetoresistance effect element portion 40 and the selector portion 50.

Note that the X, Y and Z directions shown in the drawing are directions which intersect each other. More specifically, the X, Y, and Z directions are orthogonal to each other.

FIG. 2 is a cross-sectional view schematically showing the magnetic memory device, in particular, a detailed configuration of the memory cell 30.

The memory cell 30 includes the magnetoresistance effect element portion 40, the selector portion (switching element portion) 50, the intermediate portion 60, an upper layer portion 70 and a sidewall insulating portion 80.

The magnetoresistance effect element portion 40 is a magnetic tunnel junction (MTJ) element portion and constituted by a stacked structure of a storage layer (first magnetic layer) 41, a reference layer (second magnetic layer) 42 and a tunnel barrier layer (nonmagnetic layer) 43.

The storage layer 41 is a ferromagnetic layer having a variable magnetization direction. The reference layer 42 is a ferromagnetic layer having a fixed magnetization direction. The tunnel barrier layer 43 is an insulating layer provided between the storage layer 41 and the reference layer 42. Note that the variable magnetization direction means that the magnetization direction varies with respect to a predetermined write current. The fixed magnetization direction means that the magnetization direction does not vary with respect to a predetermined write current.

When the magnetization direction of the storage layer 41 is parallel to that of the reference layer 42, the magnetoresistance effect element portion 40 is in a low-resistance state where the resistance is relatively low. When the magnetization direction of the storage layer 41 is antiparallel to that of the reference layer 42, the magnetoresistance effect element portion 40 is in a high-resistance state where the resistance is relatively high. With this structure, the magnetoresistance effect element portion 40 can store binary data according to the resistance state.

Note that in FIG. 2, a bottom-free magnetoresistance effect element portion 40 in which the storage layer 41 is located on a lower layer side of the reference layer 42 is used, but a top-free magnetoresistance effect element portion in which the storage layer 41 is located on an upper layer side of the reference layer 42, may as well be used.

The selector portion 50 is provided on a lower layer side of the magnetoresistance effect element portion 40 and is electrically connected in series with the magnetoresistance effect element portion 40. The selector portion 50 is a 2-terminal switching element and contains a bottom electrode 51, a top electrode 52 and a selector material layer (switching material layer) 53 provided between the bottom electrode 51 and the top electrode 52.

The bottom electrode 51 and the top electrode 52 are each formed substantially of, for example, a conductive material such as a composition containing titanium (Ti) and nitrogen (N) (for example, titanium nitride (TiN)). The selector material layer 53 is formed of an insulating material containing a metal element. For example, the selector material layer 53 is formed substantially of a composition containing silicon (Si), oxygen (O), and a predetermined element selected from arsenic (As), phosphorus (P), antimony (Sb), sulfur (S), selenium (Se) and tellurium (Te) (that is, for example, silicon oxide (SiOₓ) containing the above predetermined element). In the specification and claims of this application, the expressions containing “substantially” (for example, “substantially formed”) and similar expressions are meant that the material (composition) substantially formed is tolerated to contain unintended impurities.

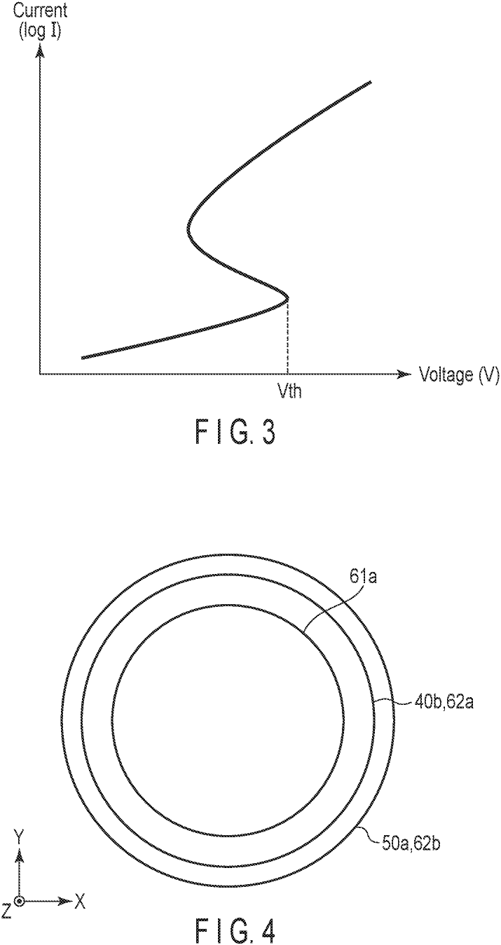

FIG. 3 is a diagram schematically showing a current-voltage characteristic of the selector portion 50. The horizontal axis indicates the voltage applied between the two terminals of the selector portion 50 (between the bottom electrode 51 and the top electrode 52), and the vertical axis indicates the current flowing between the two terminals. As shown in FIG. 3, the selector portion 50 has a characteristic which changes from an off state to an on state when the voltage applied between the two terminals becomes greater than or equal to a predetermined voltage (threshold voltage Vth).

Therefore, when the voltage applied between the bottom electrode 51 and the top electrode 52 of the selector portion 50 reaches or exceeds the threshold voltage Vth, current is allowed to flow through the conductive portion 62, described later, to the magnetoresistance effect element portion 40 and the selector portion 50, thereby making it possible to carry out write or read to the magnetoresistance effect element portion 40.

The intermediate portion 60 includes a buffer insulating portion 61 and a conductive portion 62.

The buffer insulating portion 61 is provided between the magnetoresistance effect element portion 40 and the selector portion 50. The buffer insulating portion 61 is formed substantially of an insulating material such as a composition containing silicon (Si) and oxygen (O) (for example, silicon oxide (SiOₓ)), a composition containing silicon (Si) and nitrogen (N) (for example, silicon nitride (SiNₓ)) or the like. In this embodiment, the buffer insulating portion 61 is formed of silicon oxide.

The conductive portion 62 is provided between the magnetoresistance effect element portion 40 and the selector portion 50. The conductive portion 62 surrounds a side surface of the buffer insulating portion 61 and is provided along the side surface of the buffer insulating portion 61. The conductive portion 62 is formed substantially of a conductive material such as a composition containing titanium (Ti) and nitrogen (N) (for example, titanium nitride (TiN)), tantalum (Ta) or the like. In this embodiment, the conductive portion 62 is formed of titanium nitride.

The conductive portion 62 electrically connects the magnetoresistance effect element portion 40 and the selector portion 50 to each other. That is, a lower end of the conductive portion 62 is connected to the top electrode 52 of the selector portion 50, and an upper end of the conductive portion 62 is connected to the storage layer 41 of the magnetoresistance effect element portion 40. As already mentioned, either one of the bottom-free and top-free magnetoresistance effect element portions can be used for the magnetoresistance effect element portion 40. Therefore, generally, the upper end of the conductive portion 62 is connected to the magnetic layer located on the lower layer side, of the storage layer 41 and the reference layer 42. Thus, since the upper end of the conductive portion 62 is connected to the magnetoresistance effect element portion 40, the conductive portion 62 can effectively functions as the bottom electrode for the magnetoresistance effect element portion 40.

FIG. 4 is a diagram schematically showing the magnetoresistance effect element portion 40, the selector portion 50, the buffer insulating portion 61, and the conductive portion 62 in relation with each other as viewed from the Z direction (the direction in which the magnetoresistance effect element portion 40, the buffer insulating portion 61 and the selector portion 5o are arranged).

As shown in FIG. 4, as viewed from the Z direction, the pattern of an upper surface of the buffer insulating portion 61 (an outer circumference 61a of the upper surface) is located inside the pattern of a lower surface of the magnetoresistance effect element portion 40 (an outer circumference 40b of the lower surface). Also, as viewed from the Z direction, the outer circumference 62a of the upper surface of the conductive portion 62 is aligned with the outer circumference 40b of the lower surface of the magnetoresistance effect element portion 40. Further, as viewed from the Z direction, the outer circumference 62b of the lower surface of the conductive portion 62 is aligned with the outer circumference 50a of the upper surface of the selector portion 50.

In FIG. 2, the upper layer portion 70 has the functions as the top electrode for the magnetoresistance effect element portion 40, and includes a ruthenium (Ru) layer 71 and a tungsten (W) layer 72.

The sidewall insulating portion 80 is provided along the sidewall of the magnetoresistance effect element portion 40 and the sidewall of the upper layer 70, and has the functions as a protective layer for the magnetoresistance effect element portion 40. The sidewall insulating portion 80 is formed of an insulating material different from the insulating material of the buffer insulating portion 61. More specifically, the sidewall insulating portion 80 is formed substantially of an insulating material such as a composition containing silicon (Si) and nitrogen (N) (for example, silicon nitride (SiNₓ)) or a composition containing silicon (Si) and oxygen (O) (for example, silicon oxide (SiOₓ)). In this embodiment, the sidewall insulating portion 80 is formed of silicon nitride.

Next, a method of manufacturing the magnetic memory device according to this embodiment will be described with reference to FIGS. 5 to 12 and FIG. 2.

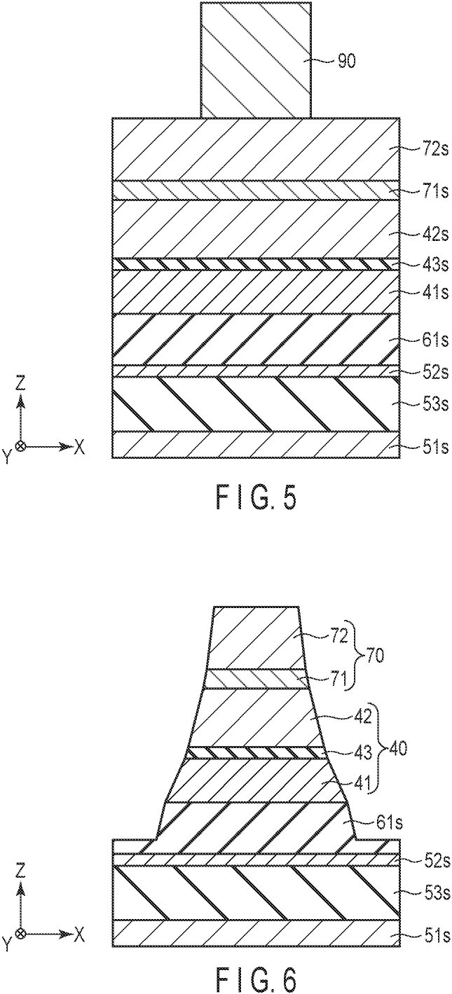

First, as shown in FIG. 5, a stacked film is formed on a lower structure (not shown) including a semiconductor substrate or the like. More specifically, as the stacked film, a bottom electrode layer 51s, a selector material layer 53s, a top electrode layer 52s, a buffer insulating layer 61s, a storage layer 41s, a tunnel barrier layer 43s, a reference layer 42s, a ruthenium (Ru) layer 71s and a tungsten (W) layer 72s are formed. Subsequently, a pattern of a carbon (C) layer is formed as a hard mask 90 on the W layer 72s.

Next, as shown in FIG. 6, the patterning is performed by IBE using the hard mask 90 as a mask. As a result, patterns of the W layer 72, the Ru layer 71, the reference layer 42, the tunnel barrier layer 43 and the storage layer 41 are formed. In other words, the pattern of the upper layer portion 70 and the pattern of the magnetoresistance effect element portion 40 are formed. Further, the upper portion of the buffer insulating layer 61s is etched. In the example illustrated in the figure, the hard mask 90 is vanished, but the hard mask 90 may partially remain.

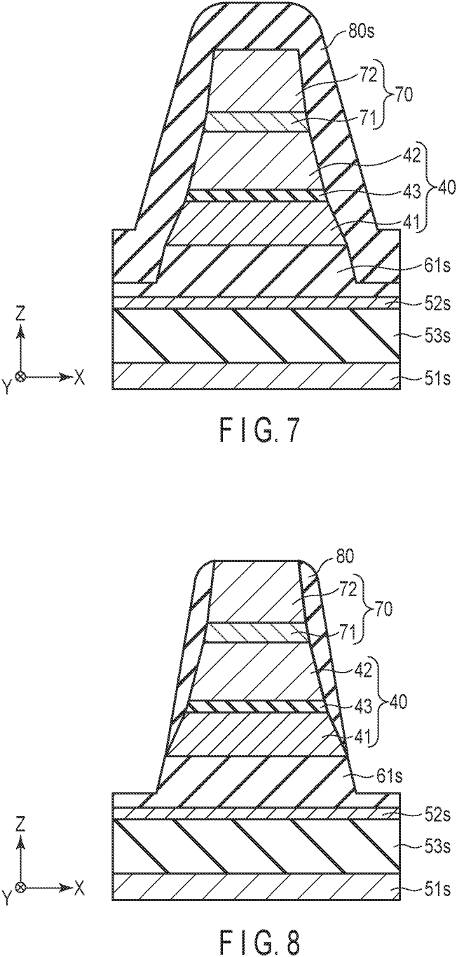

Next, as shown in FIG. 7, a sidewall insulating layer 80s is formed to cover the structure obtained in the processing step shown in FIG. 6.

Then, as shown in FIG. 8, the sidewall insulating layer 80s is etched by reactive ion etching (RIE) or ion beam etching (IBE). Thus, the sidewall insulating portion 80 is formed along the sidewall of the magnetoresistance effect element portion 40 and the sidewall of the upper layer portion 70.

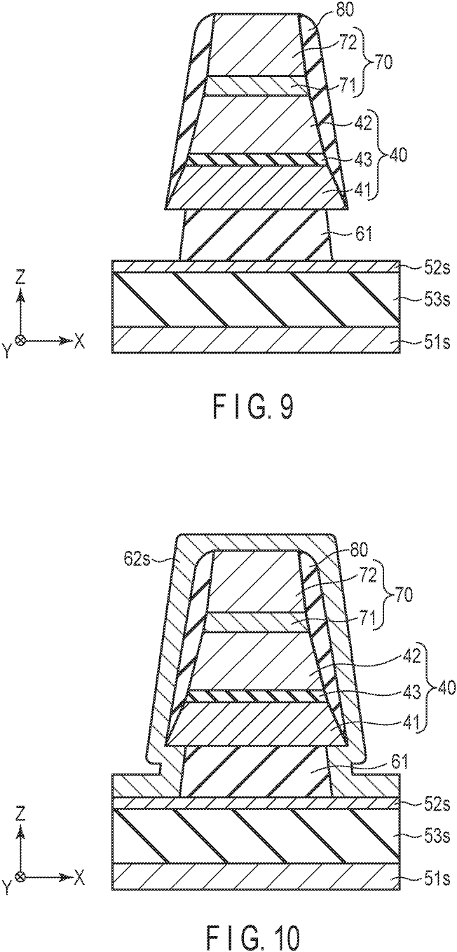

Next, as shown in FIG. 9, a part of the buffer insulating layer 61s is removed. At this time, the buffer insulating layer 61s is selectively etched so as not to remove the sidewall insulating portion 80. For the selective etching, dry etching or wet etching may be used. With the etching process, the buffer insulating portion 61 is obtained.

Next, as shown in FIG. 10, the conductive layer (TiN layer) 62s is formed by atomic layer deposition (ALD) so as to cover the structure obtained in the processing step shown in FIG. 9.

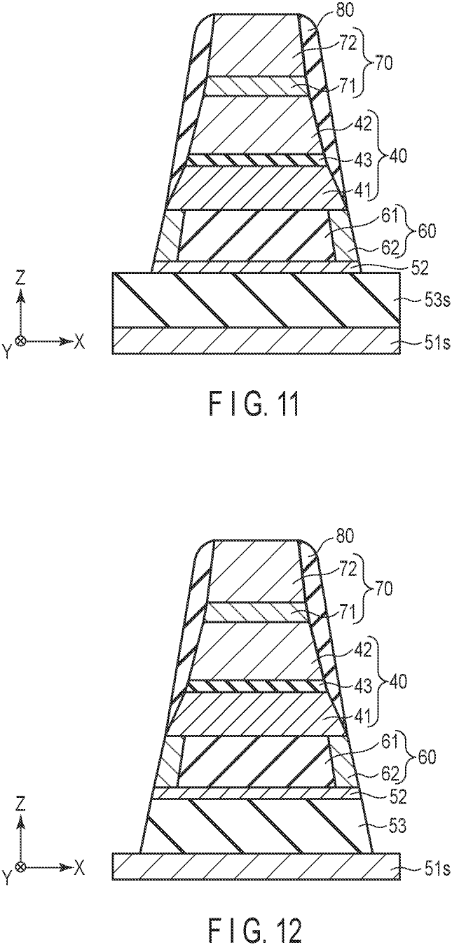

Next, as shown in FIG. 11, the conductive layer 62s and the top electrode layer 52s are etched by RIE. As a result, the conductive layer 62s remains only on the side surface of the buffer insulating portion 61, and thus the conductive portion 62 is obtained. Further, the top electrode 52 is formed under the buffer insulating portion 61 and under the conductive portion 62.

Next, as shown in FIG. 12, the selector material layer 53s is etched by RIE. Thus, the pattern of the selector material layer 53 is obtained.

After that, as shown in FIG. 2, the bottom electrode layer 51s is etched by RIE. As a result, the pattern of the bottom electrode 51 is obtained. In this manner, a magnetic memory device having such a memory cell structure as shown in FIG. 2 is formed.

As described above, in this embodiment, the buffer insulating portion 61 is provided between the magnetoresistance effect element portion 40 and the selector portion 50. The side surface of the buffer insulating portion 61 is surrounded by the conductive portion 62. With this configuration, a magnetic memory device having excellent characteristics can be obtained in this embodiment, as will be described below.

The magnetoresistance effect element portion contains magnetic elements such as iron (Fe) and cobalt (Co), and therefore it is difficult to form a pattern of the magnetoresistance effect element portion by normal etching. Therefore, in many cases, the ion beam etching (IBE) is employed to form the pattern of the magnetoresistance effect element portion. In this case, magnetic elements (metal elements) contained in the magnetoresistance effect element portion may adhere to the side surface of the selector portion, which may adversely affect the selector portion. Further, metal element such as arsenic (As), phosphorus (P), antimony (Sb), sulfur (S), selenium (Se) and tellurium (Te) contained in the selector portion may adhere to the side surface of the magnetoresistance effect element portion, which may adversely affect the magnetoresistance effect element portion.

In this embodiment, the buffer insulating portion 61 is provided between the magnetoresistance effect element portion 40 and the selector portion 50. Therefore, when forming the pattern of the magnetoresistance effect element portion 40 by IBE in the processing step shown in FIG. 6, the layers for the selector portion 50 (that is, the bottom electrode layer 51s, the top electrode layer 52s and the selector material layer 53s) are protected by the buffer insulating layer 61s. Therefore, it is possible to prevent the metal elements (magnetic elements) contained in the magnetoresistance effect element portion 40 from reaching the layers for the selector portion 50. Here, let us suppose that the buffer insulating layer 61s is etched in the processing step shown in FIG. 6. In the case, there rises no particular problem even if etching products of the buffer insulating layer 61s adhere to the side surface of the magnetoresistance effect element portion 40 because the buffer insulating layer 61s is formed of an insulating material such as silicon oxide or the like.

Further, according to this embodiment, in the processing steps shown in FIGS. 11, 12 and 2, the side surface (sidewall) of the magnetoresistance effect element portion 40 are covered by the sidewall insulating portion 80 while etching the conductive layer 62s, the top electrode layer 52s, the selector material layer 53s and the bottom electrode layer 51s. With this structure, the etching products created in the etching process shown in FIGS. 11, 12 and 2 described above are prevented from adhering to the side surface of the magnetoresistance effect element portion 40.

Further, in this embodiment, the side surface of the buffer insulating portion 61 are surrounded by the conductive portion 62, and the magnetoresistance effect element portion 40 and the selector portion 50 are electrically connected to each other by the conductive portion 62. With this structure, it is possible to ensure electrical connection between the magnetoresistance effect element portion 40 and the selector portion 50 even if the buffer insulation portion 61 is provided.

As described above, in this embodiment, it is possible to obtain a magnetic memory device including a memory cell with excellent reliability and characteristics.

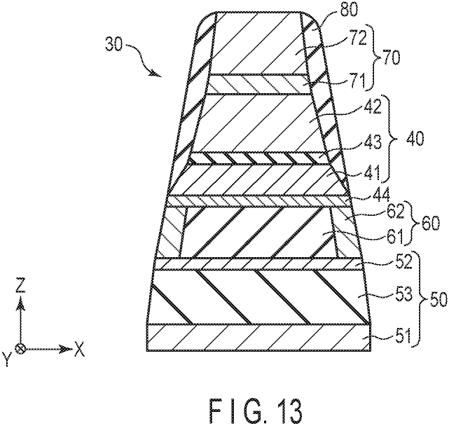

FIG. 13 is a cross-sectional view schematically showing a magnetic memory device according to a modified example of this embodiment. In the modified example, the magnetoresistance effect element portion 40 is provided with a bottom electrode 44, and the bottom electrode 44 is connected to the conductive portion 62.

The modified example has a basic structure similar to that of the embodiment described above, and advantageous effects similar to those of the embodiment described above can be obtained in this modified example as well.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
a magnetoresistance effect element portion;
a switching element portion provided on a lower layer side of the magnetoresistance effect element portion;
a buffer insulating portion provided between the magnetoresistance effect element portion and the switching element portion; and
a conductive portion surrounding a side surface of the buffer insulating portion and electrically connecting the magnetoresistance effect element portion and the switching element portion to each other.

2. The device of claim 1, wherein
a pattern of an upper surface of the buffer insulating portion is located inside a pattern of a lower surface of the magnetoresistance effect element portion as viewed from a direction in which the magnetoresistance effect element portion, the buffer insulating portion, and the switching element portion are arranged.

3. The device of claim 1, wherein
an outer circumference of an upper surface of the conductive portion is aligned with an outer circumference of a lower surface of the magnetoresistance effect element portion as viewed from a direction in which the magnetoresistance effect element portion, the buffer insulating portion and the switching element portion are arranged.

4. The device of claim 1, wherein
an outer circumference of a lower surface of the conductive portion is aligned with an outer circumference of an upper surface of the switching element portion as viewed from a direction in which the magnetoresistance effect element portion, the buffer insulating portion and the switching element portion are arranged.

5. The device of claim 1, wherein
the buffer insulating portion contains silicon (Si) and oxygen (O), or silicon (Si) and nitrogen (N).

6. The device of claim 1, wherein
the switching element portion includes a bottom electrode, a top electrode and a switching material layer provided between the bottom electrode and the top electrode.

7. The device of claim 6, wherein
the switching material layer is formed of an insulating material containing a metal element.

8. The device of claim 6, wherein
the conductive portion is connected to the top electrode of the switching element portion.

9. The device of claim 1, wherein
the switching element portion changes from an off state to an on state when voltage applied between terminals thereof becomes greater than or equal to a predetermined voltage.

10. The device of claim 1, wherein
the magnetoresistance effect element portion includes a first magnetic layer having a variable magnetization direction, a second magnetic layer having a fixed magnetization direction and a nonmagnetic layer provided between the first magnetic layer and the second magnetic layer.

11. The device of claim 10, wherein
the conductive portion is connected to a magnetic layer located on a lower layer side, of the first magnetic layer and the second magnetic layer.

12. The device of claim 1, further comprising:
a sidewall insulating portion provided along a sidewall of the magnetoresistance effect element portion.

13. The device of claim 12, wherein
the sidewall insulating portion is formed of a material different from a material of the buffer insulating portion.

14. The device of claim 1, further comprising:
a first wiring line extending in a first direction; and
a second wiring line extending in a second direction intersecting the first direction, wherein
a structure including the magnetoresistance effect element portion, the switching element portion and the buffer insulating portion is provided between the first wiring line and the second wiring line.
